(19) United States
(12) Patent Application Publication
(10) Pub. No.: US 2011/0316576 A1
(43) Pub. Date: Dec. 29, 2011

(54) Probe Card

(76) Inventors: Kenichi Kataoka, Yamanashi (JP); Jun Mochizuki, Yamanashi (JP)

(21) Appl. No.: 13/255,412

(22) PCT Filed: Feb. 15, 2010
(86) PCT No.: PCT/JP2010/052180

§ 371 Date: Sep. 16, 2011

(30) Foreign Application Priority Data
Mar. 12, 2009 (JP) 2009-060274

(51) Int. Cl. G01R 31/00

(52) U.S. Cl. 324/756.03

(57) ABSTRACT

Disclosed is a probe card including: a circuit board; a supporting plate installed below the circuit board and supporting a plurality of contact members contacting a subject to be inspected during inspection; an elastic member installed below the circuit board and above the supporting plate and having flexibility with gas filled therein, and applying a predetermined contact pressure to the plurality of contact members when the plurality of contact members contact the subject to be inspected; and a conductive section placed in the elastic member and electrically connecting the circuit board and the contact members during inspection, and the conductive section includes a conductive layer that includes an insulating layer having flexibility and a wiring layer formed on the insulating layer.

### TECHNICAL FIELD

The present invention relates to a probe card for inspecting an electrical characteristic of an inspected subject (e.g., a subject to be inspected).

### BACKGROUND ART

For example, an electrical characteristic of an electronic circuit such as an IC and an LSI formed on a semiconductor wafer (hereinafter, referred to as a ‘wafer’) is inspected by using, for example, a probe apparatus having a probe card and a placing table holding the wafer. The probe card generally includes plural contact members contacting electrode pads of the electronic circuit on the wafer, a supporting plate supporting the contact members on the bottom of the supporting plate, and a circuit board installed above the supporting plate and transmitting an inspection electrical signal to each contact member. In addition, by transmitting the electrical signal to each contact member from the circuit board while each contact member contacts each electrode pad of the wafer, the electronic circuit on the wafer is inspected.

In order to appropriately inspect the electrical characteristic of the electronic circuit, the contact member and the electrode pad need to contact each other by a predetermined contact pressure. Therefore, installing an extensible fluid chamber filled with gas therein between the circuit board and the supporting plate supporting contact member has been traditionally proposed. Wirings connected with the contact member are formed on the supporting plate and the supporting plate extends to the outside of the fluid chamber. Outside the fluid chamber, the wirings of the supporting plate are connected to the circuit board, and as a result, the contact member and the circuit board are electrically connected with each other. In addition, at the time of inspecting the electronic circuit, the supporting plate is pressed by injecting gas into the fluid chamber to contact the contact member and the electrode pad with each other by a predetermined contact pressure (Patent Document 1).

### PRIOR ART DOCUMENT

[Patent Document 1] Japanese Unexamined Patent Application Publication No. H07 (1995)-94561

### DISCLOSURE

### Technical Problem

However, in recent years, a pattern of the electronic circuit is miniaturized, such that the electrode pad is miniaturized and a gap between the electrode pads is narrowed. Further, since the wafer itself is also upsized, the number of electrode pads formed on the wafer is significantly increased. As a result, a great number of contact members or wirings corresponding thereto need to be installed even in the probe card.

Under the situation, as described above, in order to connect the wirings of the supporting plate and the circuit board to each other at the outside of the fluid chamber, the wirings should be formed at very small intervals in a narrow region of the outside of the fluid chamber, and as a result, it is actually difficult to connect the wirings and the circuit board to each other.

Further, when the wirings are placed at the outside of the fluid chamber, the lengths of the wirings from the contact member to the circuit board are different for each contact member, and as a result, there are some cases where transferring methods of the electric signal transmitted from the circuit board to the contact members are different for each contact member during inspection. As a result, the electrical characteristic of the inspected subject cannot be appropriately inspected.

The present invention has been made in an effort to appropriately perform inspection while stabilizing contact between the inspected subject and the contact member at the time of inspecting the electrical characteristic of the inspected subject such as the wafer with the plural electrode pads.

### Technical Solution

An exemplary embodiment of the present invention provides a probe card for inspecting electrical characteristics of an inspected subject, including: a circuit board; a supporting plate installed below the circuit board and supporting a plurality of contact members contacting the inspected subject during inspection; an elastic member installed below the circuit board and above the supporting plate and having flexibility with gas filled therein, and applying a predetermined contact pressure to the plurality of contact members when the plurality of contact members contact the inspected subject; and a conductive section placed in the elastic member and electrically connecting the circuit board and the contact members during inspection, and the conductive section includes a conductive layer which includes an insulating layer having flexibility and a wiring layer formed on the insulating layer.

According to the exemplary embodiment, since the conductive section, electrically connecting the circuit board and the contact members during inspection, is installed within the elastic member installed below the circuit board and above the supporting plate, wirings do not need to be formed at very small intervals within a narrow region as in the related art, and the conductive sections may be smoothly placed at the same intervals as the contact members. Therefore, the probe card of the exemplary embodiment may be adopted even in an inspected subject such as a wafer on which plural electrode pads are formed.

Further, since the elastic member is installed between the circuit board and the supporting plate, the elastic member presses the supporting plate to stably contact the inspected subject and the contact member by the predetermined contact pressure. Moreover, since each conductive layer includes the insulating layer having flexibility, the conductive section may be extended vertically. Therefore, in order to contact the inspected subject and the contact member by the predetermined contact pressure during inspection, even when the contact member is pressed and moved down by the elastic member, the conductive section may be extended vertically to surely keep electrical connection between the circuit board and the contact member.

Further, since the conductive section is installed above the supporting plate, the lengths of wirings between the contact members and the circuit board are the same for each contact member. Accordingly, the transferring methods of the electrical signal to the contact member from the circuit board are the same for each contact member.

Therefore, when the probe card of the exemplary embodiment of the present invention is used, the electrical characteristic of the inspected subject can be appropriately inspected.

Another exemplary embodiment of the present invention provides a probe card for inspecting electrical characteristics of an inspected subject, including: a circuit board; a supporting plate installed below the circuit board and supporting a plurality of contact members contacting the inspected subject during inspection; an elastic member installed between the circuit board and the supporting plate and applying a predetermined contact pressure to the plurality of contact members when the plurality of contact members contact the inspected subject; and a conductive section placed below the circuit board and above the supporting plate and electrically connecting the circuit board and the contact members during inspection. The conductive section includes a plurality of conductive layers placed vertically, the uppermost of the plurality of conductive layers has one end that is electrically connected with the circuit board during inspection and the other end that is fixed and electrically connected to the end of a conductive layer placed below the conductive layer, and the lowermost of the plurality of conductive layers has one end that is electrically connected with the contact member during inspection and the other end that is fixed and electrically connected to the end of a conductive layer placed above the conductive layer. When a conductive layer as an intermediate layer is placed between the uppermost conductive layer and the lowermost conductive layer, one end of the intermediate conductive layer is fixed and electrically connected to the end of the conductive layer placed above the intermediate conductive layer and the other end of the intermediate conductive layer is fixed and electrically connected to the end of the conductive layer placed below the intermediate conductive layer. And the conductive layer includes an insulating layer having flexibility and a wiring layer formed on the insulating layer.

### Advantageous Effects

According to exemplary embodiments of the present invention, it is possible to appropriately perform inspection while stabilizing contact between an inspected subject and a contact member at the time of inspecting the electrical characteristic of the inspected subject.

### DESCRIPTION OF DRAWINGS

FIG. 1 is a longitudinal cross-sectional view schematically showing a configuration of a probe apparatus having a probe card according to an exemplary embodiment.

FIG. 2 is a transverse cross-sectional view schematically showing a configuration of a probe card.

FIG. 3 is a longitudinal cross-sectional view schematically showing a configuration of a conductive section.

FIG. 4 is a perspective view of a conductive layer.

FIG. 5 is a plan view of an insulating film where plural insulating layers and plural wiring layers are formed thereon.

FIG. 6 is an explanatory diagram showing a state in which inspection is performed by using a probe apparatus.

FIG. 7 is an explanatory diagram showing a state in which inspection is performed by using a probe apparatus.

FIG. 8 is a longitudinal cross-sectional view schematically showing a configuration of a conductive section according to another exemplary embodiment.

FIG. 9 is a plan view of an insulating film according to another exemplary embodiment.

FIG. 10 is a longitudinal cross-sectional view schematically showing a configuration of a conductive section according to another exemplary embodiment.

FIG. 11 is a longitudinal cross-sectional view schematically showing a configuration of a probe apparatus according to another exemplary embodiment.

[Description of Reference Numerals]

| | |
|---|---|
| 1: Probe apparatus | 2: Probe card |
| 3: Placing table | 10: Circuit board |
| 11: Probe | 12: Supporting plate |
| 13: Connection terminal | 14: Reinforcement member |
| 15: Holder | 16: Connection terminal |
| 17: Connection wiring | 18: Supporting member |
| 20: Fluid chamber | 21: Air supply pipe |
| 30: Conductive section | 31-34: Conductive layer |
| 35: Space part | 40: Insulating layer |
| 41: Wiring layer | 42: Conducting portion |
| 43: Insulating film | 44: Notch |
| 45: base portion | 46: Resin |
| 50, 51: Connection portion | 52: Wire |
| 53: Resin | 54: Conductive paste |
| 60: Actuator | U: Electrode pad |
| W: Wafer | |

### BEST MODE

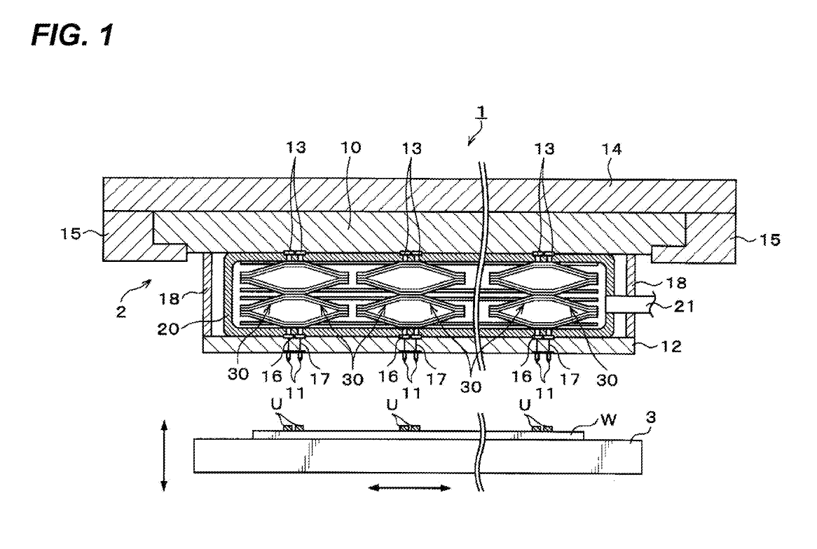

Hereinafter, exemplary embodiments of the present invention will be described. FIG. 1 is a longitudinal cross-sectional view schematically showing a configuration of a probe apparatus 1 having a probe card according to an exemplary embodiment.

In probe apparatus 1, for example, a probe card 2 and a placing table 3 on which a wafer W as an inspected subject is placed are installed. Probe card 2 is placed above placing table 3.

Probe card 2 has, for example, a substantially disk shape on the whole. Probe card 2 includes a circuit board 10 for transmitting an inspection electrical signal to wafer W placed on placing table 3, and a supporting plate 12 supporting probes 11 on the bottom of supporting plate 12, where probes 11 serve as plural contact members contacting electrode pads U of wafer W during inspection.

Circuit board 10 has, for example, a substantially disk shape and is electrically connected to a tester (not shown). In circuit board 10, an electronic circuit (not shown) is mounted for transmitting the inspection electrical signal between circuit board 10 and probes 11. The inspection electrical signal from the tester is transmitted to and received from probes 11 through the electronic circuit of circuit board 10. On the bottom of circuit board 10, plural connection terminals 13 are placed to correspond to probes 11 of supporting plate 12. Connection terminal 13 is formed as a part of the electronic circuit of circuit board 10.

On the top of circuit board 10, a reinforcement member 14 reinforcing circuit board 10 is installed in parallel to circuit board 10. Reinforcement member 14 has, for example, a substantially disk shape. A holder 15 is installed on the outer periphery of circuit board 10. Circuit board 10 and reinforcement member 14 are held by holder 15.

Supporting plate 12 has, for example, a substantially disk shape and is placed below plural connection terminals 13 of circuit board 10 to face placing table 3. Further, plural probes 11 supported on the bottom of supporting plate 12 are placed to correspond to electrode pads U of wafer W. On the top of supporting plate 12, plural connection terminals 16 are installed. Connection terminals 16 are electrically connected with probes 11 through connection wirings 17. Further, as for probes 11, a metallic conductive material such as nickel cobalt is used. Further, as supporting plate 12, a material having an insulating property and having substantially the same thermal expansion ratio as wafer W is used and, for example, an insulating material such as ceramic or glass or a conductive material of which the surface is coated is used.

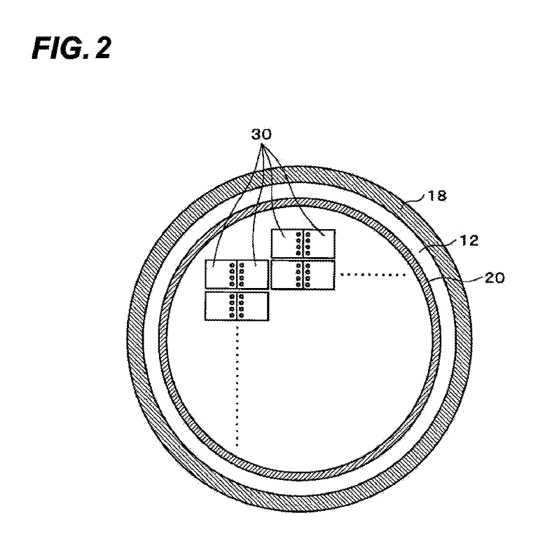

On the outer peripheral top of supporting plate 12, a supporting member 18 having elasticity is installed in an annular shape as shown in FIG. 2. Supporting member 18 is connected to circuit board 10 to support supporting plate 12 as shown in FIG. 1. Further, supporting member 18 may be connected to, for example, holder 15.

A fluid chamber 20 is installed as an elastic member between circuit board 10 and supporting plate 12. Fluid chamber 20 is installed to cover a substantially entire surface of the top of supporting plate 12. Fluid chamber 20 may be filled with gas, for example, compressed air therein and has flexibility. Fluid chamber 20 is provided with an air supply pipe 21 for injecting and discharging the compressed air into and from fluid chamber 20. Air supply pipe 21 is connected to a compressed air supplying source (not shown). In addition, when a predetermined quantity of compressed air is filled in fluid chamber 20, fluid chamber 20 expands vertically, such that the top of fluid chamber 20 is contacted to the bottom of circuit board 10 and the bottom of fluid chamber 20 is contacted to the top of supporting plate 12. In this case, since reinforcement member 14 is fixed, supporting plate 12 may be uniformly pressed in a horizontal plane and moved downward and plural probes 11 supported on supporting plate 12 may also be moved downward. Therefore, fluid chamber 20 may apply a predetermined contact pressure to plural probes 11 during inspection. Further, in order to prevent fluid chamber 20 from moving in a horizontal direction, the bottom of fluid chamber 20 may adhere to the top of supporting plate 12 or a guide (not shown) may be installed in the vicinity of fluid chamber 20. Further, fluid chamber 20 is formed, for example, by placing plural conductive sections 30 to be described below between two flexible films and thereafter, sealing the two flexible films.

Inside fluid chamber 20, plural conductive sections 30 are installed, which are electrically connecting connection terminals 13 of circuit board 10 and probes 11 of supporting plate 12 to each other during inspection. Conductive sections 30 are placed at locations corresponding to connection terminals 13 and probes 11, that is, below circuit board 10 and above supporting plate 12. Further, plural conductive sections 30 are placed in parallel and in a horizontal direction within fluid chamber 20 as shown in FIG. 2.

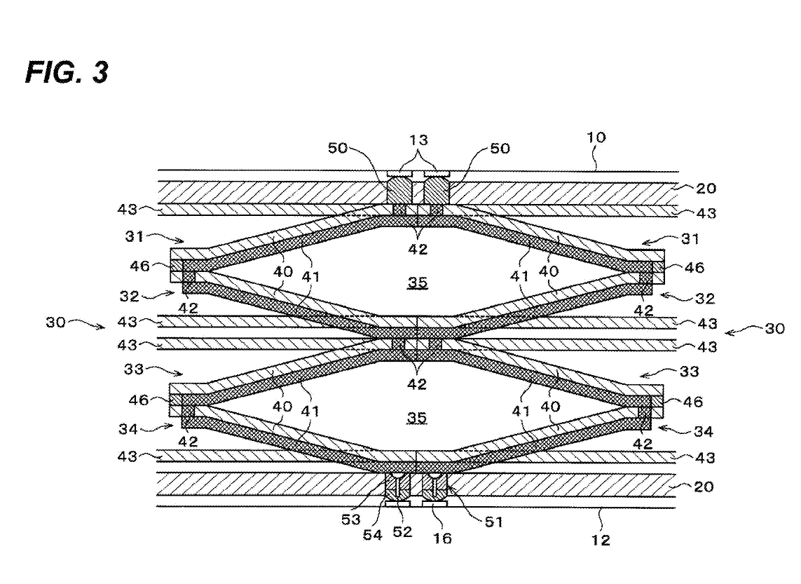

Conductive sections 30 include plural, for example, four conductive layers 31, 32, 33, and 34 placed vertically as shown in FIG. 3. Further, FIG. 3 shows, for example, a case in which fluid chamber 20 expands during inspection. In addition, the number of stacked conductive layers is not limited to the exemplary embodiment but may be five or more and three or less.

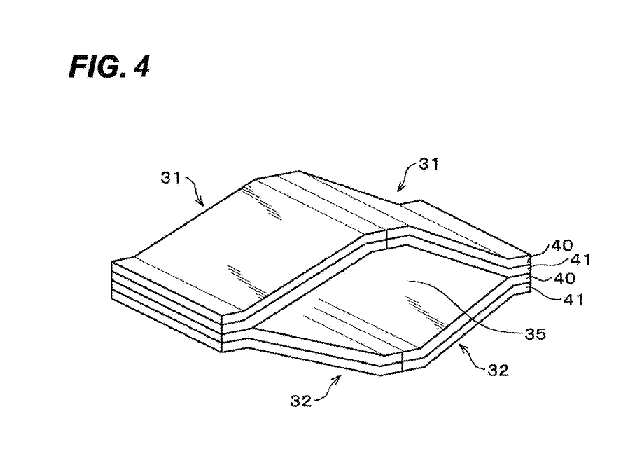

Conductive sections 30 are extended in a zigzag shape when viewed from the lateral side. In addition, conductive layers (31, 31) of conductive sections (30, 30) adjacent to each other in a horizontal direction are placed to be curved convex upwards on the whole. Further, conductive layers (32, 32) are placed to be curved convex downwards on the whole. By this configuration, as shown in FIG. 4, a space part 35 of which both lateral sides are opened is formed between conductive layers (31, 31) and conductive layers (32, 32). Further, conductive layers 33 and 34 are placed similarly and space part 35 is formed between conductive layers (33, 33) and conductive layers (34, 34) of conductive section 30 adjacent to each other. In addition, the phrase that the conductive layers are curved convex indicates that the conductive layers particularly need not to be consecutively curved. And even though the conductive layers have corner portions, it is sufficient if the conductive layers are curved on the whole.

As shown in FIG. 3, conductive layer 31 as, for example, flexible printed circuits (FPC) includes, for example, an insulating layer 40 made of a resin film having flexibility and a wiring layer 41 formed on the bottom of insulating layer 40. A conducting portion 42 is formed at the end of insulating layer 40, and connected to wiring layer 41.

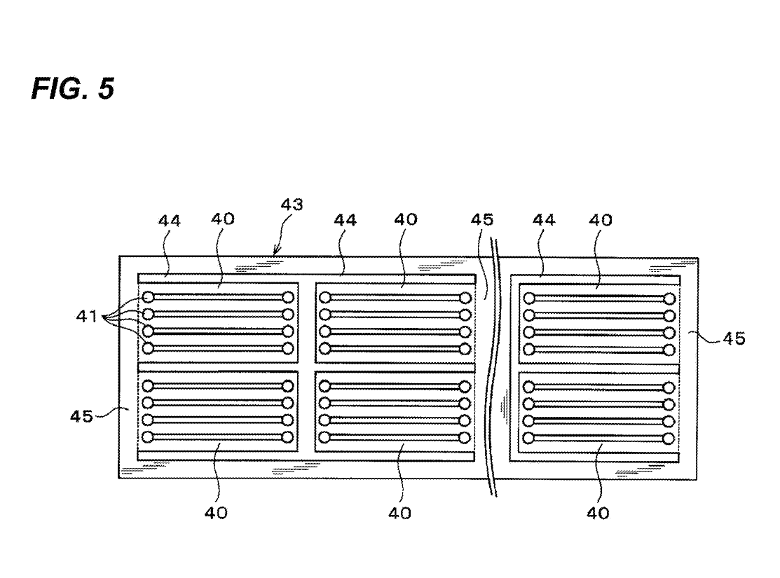

Plural insulating layers 40 of conductive layer 31 are formed on a single insulating film 43 in a horizontal direction as shown in FIG. 5. Plural insulating layers 40 are partitioned by plural notches 44 formed on insulating film 43 in a square shape when viewed from above. By this configuration, insulating layer 40 is movable vertically around a base portion 45 that does not have notch 44. Further, on the surface of insulating layer 40, plural wiring layers 41 are arranged in parallel in a horizontal direction. In addition, plural wiring layer 41 are integrally formed at predetermined locations on insulating film 43 by using a photolithography technique or an etching technique, and thereafter, plural insulating layers 40 are formed by providing plural notches 44 on insulating film 43. Accordingly, plural insulating layers 40 and plural wiring layers 41 may be integrally formed.

Conductive layers 32 to 34 also include insulating layers 40, wiring layers 41, and conducting portions 42, such as conductive layers 31. Further, plural insulating layers 40 and plural wiring layers 41 of each of conductive layers 32 to 34 are also integrally formed on one insulating film 43. That is, in plural conductive sections 30 placed in parallel in a horizontal direction shown in FIG. 2, the conductive layers positioned at the same height are integrally formed on one insulating film 43.

Between conductive layers 31 and 32, the end of wiring layer 41 of conductive layer 31 and conducting portion 42 formed at the end of insulating layer 40 of conductive layer 32 are fixed and connected, for example, by soldering. Further, even between conductive layers 32 and 33 and between conductive layers 33 and 34, the end of wiring layer 41 and the end of conducting portion 42 are fixed and connected to each other, for example, by soldering. Further, on conductive section 32, one end connected with upper conductive section 31 and the other end connected with lower conductive section 33 face each other. Similarly, even on conductive section 33, one end connected with upper conductive section 32 and the other end connected with lower conductive section 34 face each other.

Further, the end of conductive layer 31 and the end of conductive layer 32 are sealed, for example, by a resin 46. Similarly, the end of conductive layer 33 and the end of conductive layer 34 are also sealed, for example, by resin 46.

Conducting portion 42 formed at the end of wiring layer 41 of uppermost conductive layer 31 is connected to a connection portion 50 formed in fluid chamber 20. Connection portion 50 has conductivity and is placed at a position corresponding to connection terminal 13 of circuit board 10. Connection portion 50 is formed, for example, by charging conductive paste in a through-hole formed in fluid chamber 20 and thereafter, heating the conductive paste. In addition, connection portion 50 contacts connection terminal 13 to thereby electrically connect conductive layer 31 of conductive section 30 and connection terminal 13 each other. That is, by connection portion 50, conductive section 30 and connection terminal 13 can be electrically connected with each other while maintaining airtightness within fluid chamber 20. Further, connection portion 50 may be formed by inserting a solder ball into the through-hole of fluid chamber 20 described above and heating and melting the solder ball.

The end of wiring layer 41 of lowermost conductive layer 34 is connected to a connection portion 51, which is another connection portion formed in fluid chamber 20. Connection portion 51 has conductivity and is placed at a position corresponding to connection terminal 16 of supporting plate 12. Connection portion 51 is formed, for example, by performing a wire-bonding at the through-hole formed in fluid chamber 20. That is, a wire 52 is inserted into the through-hole of fluid chamber 20 and a resin 53 is filled in the through-hole so that the front end of wire 52 protrudes. In addition, a conductive paste 54 is filled in the through-hole to cover the front end of wire 52 thereby forming connection portion 51. In addition, connection portion 51 contacts connection terminal 16, such that conductive layer 32 of conductive section 30 and connection terminal 16 are electrically connected with each other and conductive layer 32 and probe 11 are electrically connected with each other. That is, by connection portion 51, conductive section 30 and probe 11 can be electrically connected with each other while maintaining airtightness in fluid chamber 20. Further, connection portion 51 contacts connection terminal 16 installed on the top of supporting plate 12 in the exemplary embodiment, but connection portion 51 may be installed to penetrate supporting plate 12 in a thickness direction and connection portion 51 may contact a connection terminal (not shown) installed on the bottom of supporting plate 12.

Placing table 3 is configured, for example, to be movable in a horizontal direction and vertically, and may move placed wafer W 3-dimensionally.

Probe apparatus 1 according to the exemplary embodiment is configured as above, and a method for inspecting the electrical characteristic of the electronic circuit of wafer W performed in probe apparatus 1 will be described.

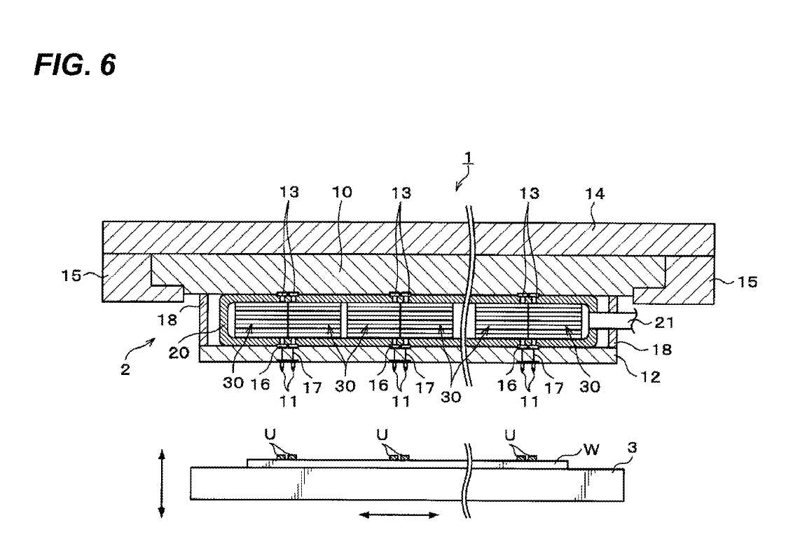

When inspection starts, compressed air is not yet supplied to the inside of fluid chamber 20, and fluid chamber 20 is in a compressed state as shown in FIG. 6. Further, conductive section 30 in fluid chamber 20 is not extended and conductive layers 31 to 34 of conductive section 30 are stacked in a horizontal direction.

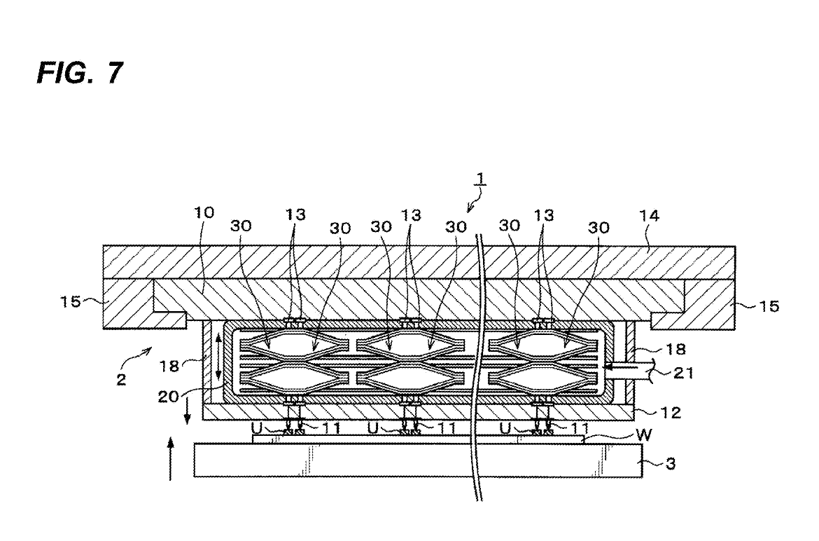

Then, wafer W is placed on placing table 3, and placing table 3 moves up to a predetermined location as shown in FIG. 7. Simultaneously or thereafter, compressed air is supplied into fluid chamber 20 from air supply pipe 21 and a predetermined quantity of compressed air is filled in fluid chamber 20. In doing so, fluid chamber 20 is expanded vertically to uniformly press down supporting plate 12 on the horizontal plane. In this case, conductive section 30 in fluid chamber 20 is also extended vertically together with expansion of fluid chamber 20. Pressed supporting plate 12 moves downward and plural probes 11 supported on supporting plate 12 also moves downward. Then, each probe 11 contacts each electrode pad U of wafer W by a predetermined contact pressure.

Further, with the vertical expansion of fluid chamber 20, connection portions 50 and 51 of fluid chamber 20 are connected to connection terminal 13 of circuit board 10 and connection terminal 16 of supporting plate 12, respectively. As a result, circuit board 10 and electrode pad U are electrically connected with each other.

In addition, while wafer W is pressed to probe 11 by a predetermined contact pressure, the inspection electrical signal is transmitted from circuit board 10 to each electrode pad U on wafer W by passing through connection portion 50, conductive section 30, connection portion 51, connection terminal 16, connection wiring 17, and probe 11 in sequence to inspect the electrical characteristic of the electronic circuit on wafer W.

According to the exemplary embodiment, since conductive section 30 electrically connecting probe 11 with circuit board 10 during inspection is installed below circuit board 10 and above supporting plate 12, wirings do not need to be formed at very small intervals within a narrow region in the related art and plural conductive sections 30 may be smoothly placed at the same intervals as probes 11. Therefore, probe card 2 of the exemplary embodiment may be adopted even in the case where plural electrode pads U are formed on wafer W.

Further, since fluid chamber 20 having flexibility is installed between circuit board 10 and supporting plate 12, a predetermined quantity of compressed air is filled in fluid chamber 20, such that supporting plate 12 can be uniformly pressed on the horizontal plane by expanding fluid chamber 20. Therefore, electrode pad U of wafer W and probe 11 may contact each other stably by a predetermined contact pressure.

Further, since the ends of the adjacent conductive layers of conductive section 30 are fixed to each other and each of conductive layers 31 to 34 includes insulating layer 40 having flexibility, conductive section 30 may be extended in a vertical direction with a zigzag shape. Therefore, even though the predetermined quantity of compressed air is filled in fluid chamber 20 and fluid chamber 20 is thus expanded vertically during inspection, conductive section 30 is extended in a vertical direction to keep the electrical connection between circuit board 10 and probe 11.

Further, since plural conductive layers 31 to 34 are stacked in conductive section 30 in a vertical direction, flexibility and extendibility of conductive section 30 can be improved. As a result, even when a vertical expansion amount of fluid chamber 20 is large, conductive section 30 may be extended in a vertical direction to surely keep the electrical connection between circuit board 10 and probe 11.

Further, since conductive section 30 is extended above supporting plate 12, the lengths of wirings between probes 11 and circuit board 10 are the same as each other for each probe 11. Accordingly, the transferring method of the electrical signal to probe 11 from circuit board 10 is the same in each probe 11.

As described above, when probe card 2 of the exemplary embodiment is used, the electrical characteristic of the electronic circuit on wafer W can be appropriately inspected while stably contacting electrode pad U of wafer W and probe 11 by the predetermined contact pressure.

Further, in plural conductive sections 30, since plural insulating layers 40 and plural wiring layers 41 can be integrally formed on one insulating film 43, plural wiring layers can be very easily formed as compared with a case in which the wiring layer is formed for each probe 11, and a manufacturing cost of probe card 2 can be remarkably reduced. Further, since the photolithography technique or etching technique is used, plural wiring layers 41 can be formed with high precision, and appropriate inspection can be performed.

In probe card 2 of the exemplary embodiment, the configuration and placement of conductive section 30 are not limited to the above exemplary embodiment.

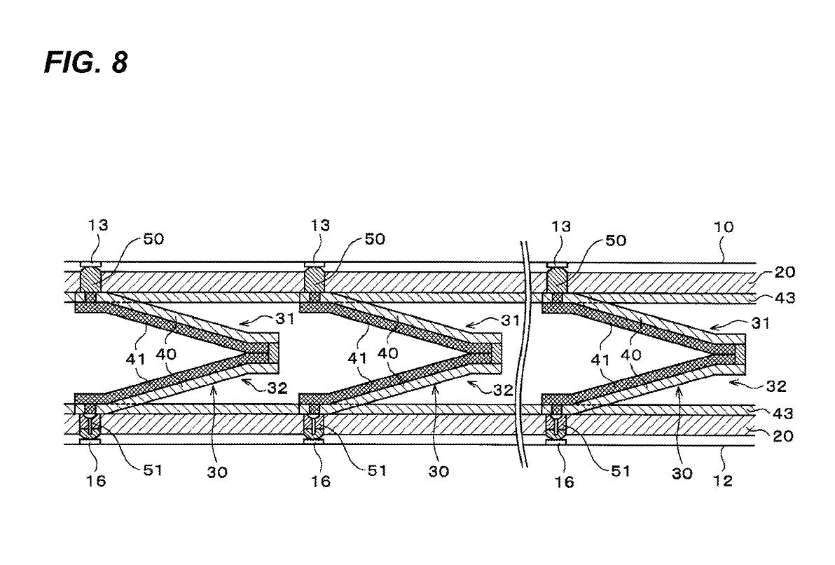

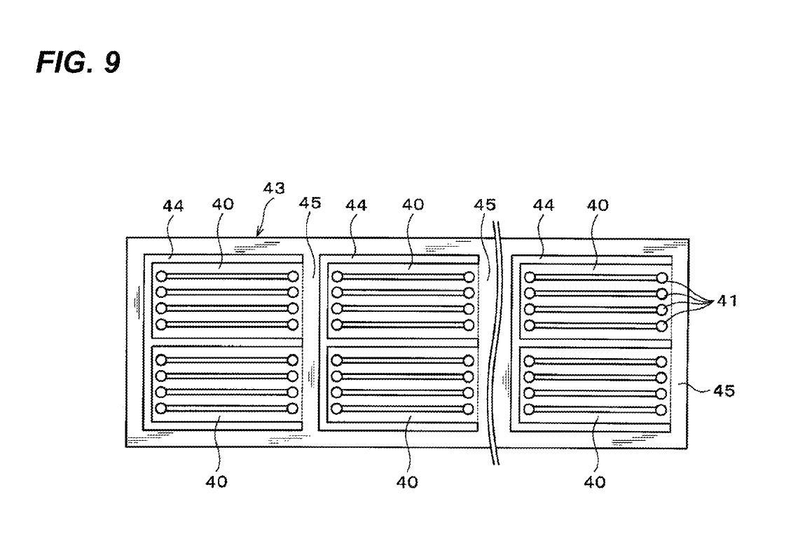

For example, as shown in FIG. 8, in conductive section 30, two conductive layers 31 and 32 may be stacked. Further, in lower conductive layer 32, wiring layer 41 is formed on the top of insulating layer 40, and the end of wiring layer 41 of upper conductive layer 31 and the end of wiring layer 41 of lower conductive layer 32 may be directly connected to each other. Further, in plural conductive sections 30 placed in a horizontal direction, conductive sections 30 may be placed without space part 35 as described in the exemplary embodiment. That is, an opening portion formed between conductive layers 31 and 32 may be placed to face one direction. In this case, as shown in FIG. 9, in insulating film 43, an opening portion of notch 44 is formed to face one direction. Further, in the present exemplary embodiment, since the other configuration of probe card 2 is the same as those of the above exemplary embodiment, a description thereof will be omitted.

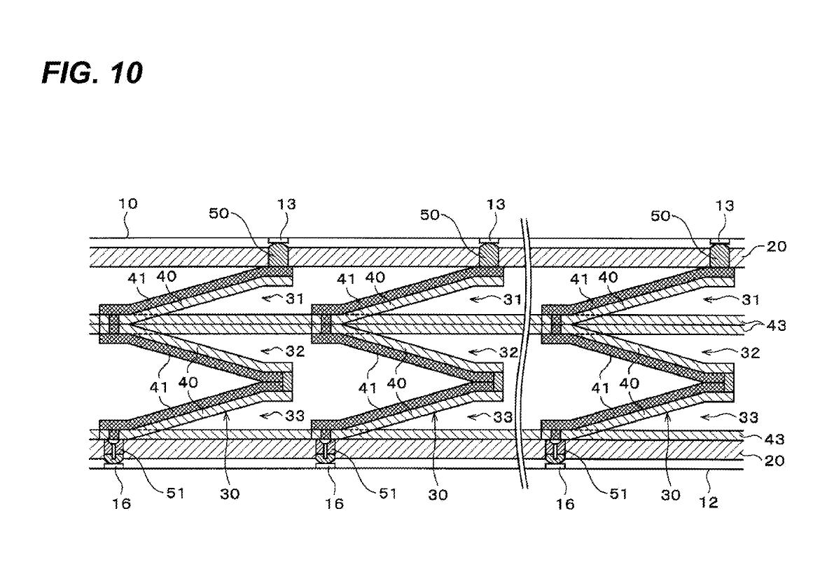

Further, for example, as shown in FIG. 10, in conductive section 30, three conductive layers 31 to 33 may be stacked. Further, in the present exemplary embodiment, since the other configuration of conductive layers 31 to 33 and probe card 2 is the same as that of the above exemplary embodiment, a description thereof will be omitted.

Further, each of conductive layers 31 and 32 of conductive section 30 may have a multilayered wiring structure in which plural insulating layers 40 and plural wiring layers 41 are alternately and vertically stacked.

Even in any one exemplary embodiment described above, since conductive section 30 can be extended in a vertical direction, the electrical characteristic of the electronic circuit on wafer W can be appropriately inspected while stably contacting electrode pad U of wafer W and probe 11 by a predetermined contact pressure.

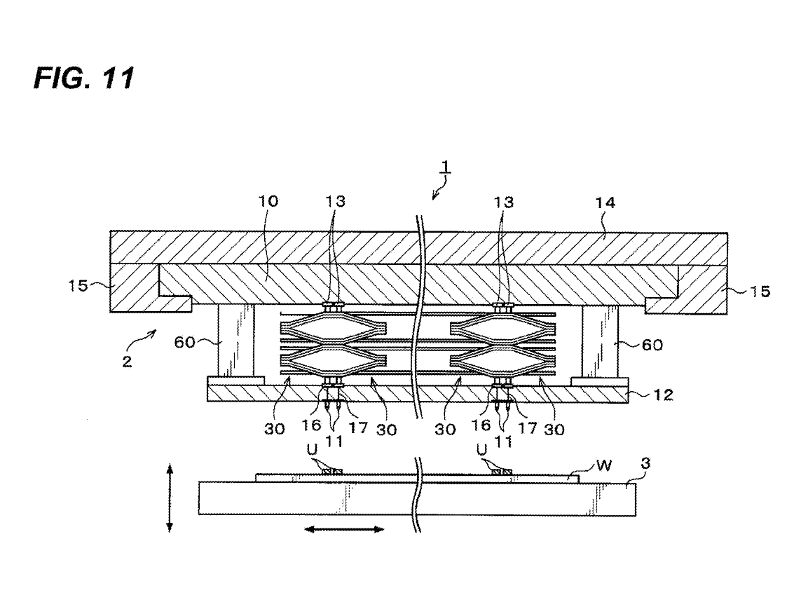

In the above exemplary embodiments, fluid chamber 20 is used as the elastic member, but if the predetermined contact pressure can be applied to plural probes 11 during inspection, the elastic member is not limited to fluid chamber 20. For example, as shown in FIG. 11, an actuator 60 may be used as the elastic member. In addition, plural actuators 60 are installed between circuit board 10 and supporting plate 12, and plural conductive sections 30 may be placed between plural actuators 60.

Actuator 60 of the exemplary embodiment, for example, generates a predetermined thrust in a predetermined direction by air. Even in this case, by injecting a predetermined quantity of air into actuator 60, actuator 60 presses supporting plate 12 to stably contact each probe 11 and each electrode pad U of wafer W by a predetermined contact pressure. Further, actuator 60 that generates a predetermined thrust by electrical energy may be used.

In fluid chamber 20 of the exemplary embodiment described above, connection portion 50 of circuit board 10 may be configured similarly to connection portion 51 described above. Further, connection portion 51 of supporting plate 12 may be configured similarly to connection portion 50 described above.

Further, in the above exemplary embodiments, probe 11 is used as the contact member, but the contact member is not limited thereto. For example, various contact members including a cantilever type probe may be used as the contact member.

As described above, although certain exemplary embodiments of the present invention has bee described in detail, it is to be understood by those skilled in the art that the spirit and scope of the present invention are not limited to the certain exemplary embodiments, but are intended to cover various modifications and changes without departing from the spirit and scope of the present invention. Accordingly, since the above-mentioned exemplary embodiments are provided to inform those skilled in the art of the scope of the present invention, it should be understood that they are exemplary in all aspects and not limited, and the present invention is just defined by the scope of the appended claims. The present invention may be adopted as well when the substrate is other type of substrates such as a flat panel display (FPD) and a mask reticle for a photomask other than the wafer.

### INDUSTRIAL APPLICABILITY

The present invention is useful to inspect an electrical characteristic of an inspected subject such as a semiconductor wafer.

1. A probe card for inspecting an electrical characteristic of a subject to be inspected, comprising:
a circuit board;
a supporting plate installed below the circuit board and configured to support a plurality of contact members contacting the subject to be inspected during inspection;
an elastic member installed below the circuit board and above the supporting plate and configured to have flexibility with gas filled therein, and configured to apply a predetermined contact pressure to the plurality of contact members when the plurality of contact members contact the subject to be inspected; and
a conductive section placed in the elastic member and configured to electrically connect the circuit board and the contact members during inspection,
wherein the conductive section includes a conductive layer that includes an insulating layer having flexibility and a wiring layer formed on the insulating layer.

2. The probe card of claim 1, wherein:
a connection portion configured to electrically connect the conductive section with the circuit board, is formed in the elastic member at a location corresponding to one end of the conductive layer,
the other connection portion configured to electrically connect the conductive section with the contact members, is formed in the elastic member at a location corresponding to the other end of the conductive layer, and
the connection portion and the other connection portion keep airtightness within the elastic member.

3. A probe card for inspecting an electrical characteristic of a subject to be inspected, comprising:
a circuit board;
a supporting plate installed below the circuit board and configured to support a plurality of contact members contacting the inspected subject during inspection;
an elastic member installed between the circuit board and the supporting plate and configured to apply a predetermined contact pressure to the plurality of contact members when the plurality of contact members contact the subject to be inspected; and
a conductive section placed below the circuit board and above the supporting plate and configured to electrically connect the circuit board and the contact members during inspection,
wherein the conductive section includes a plurality of conductive layers placed in a vertical direction,
an uppermost conductive layer is configured such that one end is electrically connected with the circuit board during inspection, and the other end is fixed and electrically connected to one end of a conductive layer placed below the uppermost conductive layer,
a lowermost conductive layer is configured such that one end is electrically connected with the contact member during inspection, and the other end is fixed and electrically connected to one end of a conductive layer placed above the lowermost conductive layer,
when a conductive layer is placed as an intermediate layer between the uppermost conductive layer and the lowermost conductive layer, one end of the intermediate conductive layer is fixed and electrically connected to one end of a conductive layer placed above the intermediate conductive layer, and the other end of the intermediate conductive layer is fixed and electrically connected to one end of a conductive layer placed below the intermediate conductive layer, and
the conductive layer includes an insulating layer having flexibility and a wiring layer formed on the insulating layer.

4. The probe card of claim 3, wherein the conductive section is extended in a zigzag shape during inspection when viewed from the lateral side.

5. The probe card of claim 3, wherein:
the conductive layer has a square shape when viewed from the above, and
the one end and the other end of the conductive layer face each other.

6. The probe card of claim 3, wherein the elastic member is a fluid chamber configured to be filled with gas therein and have flexibility.

7. The probe card of claim 6, wherein the conductive section is placed within the elastic member.

8. The probe card of claim 7, wherein:
a connection portion configured to electrically connect the conductive section with the circuit board, is formed in the elastic member at a location corresponding to one end of the uppermost conductive layer,
the other connection portion configured to electrically connect the conductive section with the contact members, is formed in the elastic member at a location corresponding to one end of the lowermost conductive layer, and
the connection portion and the other connection portion keep airtightness within the elastic member.

9. The probe card of claim 3, wherein:
a plurality of elastic members are installed between the circuit board and the supporting plate, and
the conductive section is installed between the plurality of elastic members.

10. The probe card of claim 1, wherein a plurality of wiring layers are formed on the one insulating layer in parallel and in a horizontal direction.

11. The probe card of claim 1, wherein a plurality of conductive sections are provided and in the plurality of conductive sections, a plurality of insulating layers positioned at the same height are formed on one insulating film in parallel and in a horizontal direction.

12. The probe card of claim 1, wherein the conductive layer includes a plurality of insulating layers and a plurality of wiring layers.
